(19) United States
(12) Patent Application Publication
(10) Pub. No.: US 2024/0162511 A1
(43) Pub. Date: May 16, 2024

(54) COMMON BATTERY MODULE INTERFACES FOR MICROGRID SYSTEMS

(71) Applicant: ELECTRIC POWER SYSTEMS, INC., North Logan, UT (US)

(72) Inventors: MICHAEL ARMSTRONG, North Logan, UT (US); STEVEN HALL, North Logan, UT (US); JOSEPH JAMES, Logan, UT (US); BOBBY HANSEN, North Logan, UT (US); NATHAN MILLECAM, North Logan, UT (US)

(73) Assignee: ELECTRIC POWER SYSTEMS, INC., North Logan, UT (US)

(21) Appl. No.: 18/420,415

(22) Filed: Jan. 23, 2024

Related U.S. Application Data
(63) Continuation of application No. PCT/US2022/038537, filed on Jul. 27, 2022.
(60) Provisional application No. 63/226,086, filed on Jul. 27, 2021.
(60) Provisional application No. 63/244,094, filed on Sep. 14, 2021.
(60) Provisional application No. 63/244,108, filed on Sep. 14, 2021.
(60) Provisional application No. 63/313,640, filed on Feb. 24, 2022.
(60) Provisional application No. 63/313,660, filed on Feb. 24, 2022.

(51) Int. Cl. H01M 10/44; B60L 50/60; B60L 50/64; B64F 1/35; H01M 50/35

(52) U.S. Cl. CPC H01M 10/441; B60L 50/64; B60L 50/66; B64F 1/352; H01M 50/35; B60L 2200/10; H01M 2220/20

(57) ABSTRACT

A charging ecosystem may comprise: an interconnected battery module; a first battery system comprising a first plurality of the interconnected battery modules; and a second battery system comprising a second plurality of the interconnected battery module. The first battery system may be configured for charging the second battery system. The second battery system may be configured for powering an electric vehicle. The interconnected battery module is adaptable to various interfaces with the first system and the second system.

### CROSS-REFERENCE TO RELATED APPLICATIONS

This application is a continuation of PCT Application PCT/US2022/038537 filed Jul. 27, 2022 and titled “COMMON BATTERY MODULE INTERFACES FOR MICROGRID SYSTEMS” (hereinafter the '537 Application). The '537 application claims priority to, and the benefit of, Provisional Patent Application No. 63/226,086, filed Jul. 27, 2021 and titled “MOBILE MICROGRID ECOSYSTEM,” Provisional Patent Application No. 63/244,094, filed Sep. 14, 2021 and titled “MOBILE CHARGING SYSTEM WITH BI-DIRECTIONAL DC/DC CONVERTER,” Provisional Patent Application No. 63,244,108, filed Sep. 14, 2021 and titled “FLUID MANAGEMENT SYSTEM FOR MOBILE CHARGING SYSTEM,” Provisional Patent Application No. 63/313,640, filed Feb. 24, 2022 and titled “CROSS-COMPATIBLE BATTERY MODULES FOR MICROGRID SYSTEMS,” Provisional Patent Application No. 63/313,660, filed Feb. 24, 2022 and titled “COMMON BATTERY MODULES INTERFACES FOR MICROGRID SYSTEMS.” Each disclosure of the foregoing applications is incorporated herein by reference in its entireties, including but not limited to those portions that specifically appear hereinafter, but except for any subject matter disclaimers or disavowals, and except to the extent that the incorporated material is inconsistent with the express disclosure herein, in which case the language in this disclosure shall control.

### FIELD OF INVENTION

The present disclosure generally relates to apparatus, systems and methods for common battery module interfaces for multi-integration between charging battery systems and aircraft battery systems.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may be inventions.

A battery module, for purposes of this disclosure, includes a plurality of electrically connected cell-brick assemblies. These cell-brick assemblies may, in turn, include a parallel, series, or combination of both, collection of electrochemical or electrostatic cells hereafter referred to collectively as “cells”, that can be charged electrically to provide a static potential for power or released electrical charge when needed. When cells are assembled into a battery module, the cells are often linked together through metal strips, straps, wires, bus bars, etc., that are welded, soldered, or otherwise fastened to each cell to link them together in the desired configuration.

A cell may be comprised of at least one positive electrode and at least one negative electrode. One common form of such a cell is the well-known secondary cells packaged in a cylindrical metal can or in a prismatic case. Examples of chemistry used in such secondary cells are lithium cobalt oxide, lithium manganese, lithium iron phosphate, nickel cadmium, nickel zinc, and nickel metal hydride. Such cells are mass produced, driven by an ever-increasing consumer market that demands low cost rechargeable energy for portable electronics.

Custom battery solutions may be expensive for a respective customer. Custom battery solutions may include longer lead times due to the customization desired by the customer. Custom battery solutions may be engineering intensive to meet desired characteristics by a customer.

### SUMMARY OF THE INVENTION

A charging ecosystem is disclosed herein. The charging ecosystem may comprise: an interconnected battery module comprising a housing, thermal management connections configured to interface with plumbing, power connections, and communications connections; a charging system comprising a first plurality of the interconnected battery module, each interconnected battery module in the first plurality of the interconnected battery module electrically coupled to a first positive terminal or a first negative terminal in the power connections of a first adjacent interconnected battery module in the first plurality of the interconnected battery module; and an aircraft battery system comprising a second plurality of the interconnected battery module, each interconnected battery module in the second plurality of the interconnected battery module electrically coupled to a second positive terminal or a second negative terminal in the power connections of a second adjacent interconnected battery module in the second plurality of the interconnected battery module.

In various embodiments, the interconnected battery module further comprises vent connections and a vent port, the vent connections configured to be coupled to a vent system. The vent port may be in fluid communication with a cavity disposed within the housing. The interconnected battery module may further comprise mounting connections. A support structure of the charging system may be coupled to the mounting connections for the first plurality of the interconnected battery module, and wherein a second support structure of the aircraft battery system is coupled to the mounting connections for the second plurality of the interconnected battery module. The support structure may be disposed in a vehicle configured to transport the charging system, and wherein the second support structure is disposed in an electrically powered aircraft. The charging ecosystem may further comprise a thermal management system in fluid communication with the first plurality of the interconnected battery module via the thermal management connections. The thermal management system may be configured to be fluidly coupled to the second plurality of the interconnected battery module via the thermal management connections in response to the thermal management system being fluidly coupled to the aircraft battery system during charging of the aircraft battery system.

A method of swapping battery modules is disclosed herein. The method may comprise: de-coupling a first interconnected battery module from a first battery system; de-coupling a second interconnected battery module from a second battery system; and coupling the first interconnected battery module to the second battery system, the second battery system including plumbing for fluid communication with a thermal management system, a vent for an exhaust system, and a plurality of interconnected battery modules in electrical communication with each other.

In various embodiments, the first interconnected battery module and the second interconnected battery module each comprise a vent connection and thermal management connections. The vent connection of the first interconnected battery module may fluidly couple a first internal cavity of the first interconnected battery module to the vent for the exhaust system in response to coupling the first interconnected battery module to the second battery system. The vent connection of the second interconnected battery module may isolate a second internal cavity of the second interconnected battery module from the vent for the exhaust system in response to de-coupling the second interconnected battery module from the second battery system. The method may further comprise coupling the second interconnected battery module to the first battery system. The first battery system may be a charging system for the second battery system, and the second battery system may be configured to power an electric vehicle.

A method is disclosed herein. The method may comprise: de-coupling a first interconnected battery module physically from a first thermal management system of a first battery system and electrically from a first set of adjacent interconnected battery modules in the first battery system; and installing the first interconnected battery module in a second battery system by coupling the first interconnected battery module physically to a second thermal management system of the second battery system and electrically to a second set of adjacent interconnected battery modules in the second battery system.

In various embodiments, de-coupling the first interconnected battery module further comprises de-coupling mounting interfaces from a first support structure of the first battery system. In various embodiments, installing the first interconnected battery module in the second battery system further comprises coupling the mounting interfaces to a second support structure of the second battery system. The first battery system may be a charging system for an electric vehicle, and the second battery system may be an electric vehicle battery system for the electric vehicle. The first battery system may be an electric vehicle battery system for an electric vehicle, and the second battery system may be a charging system for the electric vehicle. The first thermal management system may be the second thermal management system in response to the first battery system being configured to charge the second battery system.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and where:

FIG. 1 illustrates a perspective view of an interconnected battery module for use in various battery systems, in accordance with various embodiments;

FIG. 2 illustrates a schematic view of a battery system, in accordance with various embodiments;

FIG. 3 illustrates a perspective view of a portion of a battery system, in accordance with various embodiments;

FIG. 4 illustrates a schematic view of a charging ecosystem, in accordance with various embodiments;

FIG. 5 illustrates a method of swapping interconnected battery module between battery systems, in accordance with various embodiments.

### DETAILED DESCRIPTION

The following description is of various example embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments, without departing from the scope of the appended claims. For example, the steps recited in any of the method or process descriptions may be executed in any order and are not necessarily limited to the order presented. Moreover, many of the manufacturing functions or steps may be outsourced to or performed by one or more third parties. Furthermore, any reference to singular includes plural embodiments, and any reference to more than one component or step may include a singular embodiment or step. Also, any reference to attached, fixed, connected or the like may include permanent, removable, temporary, partial, full and/or any other possible attachment option. As used herein, the terms “coupled,” “coupling,” or any other variation thereof, are intended to cover a physical connection, an electrical connection, a magnetic connection, an optical connection, a communicative connection, a functional connection, and/or any other connection.

For the sake of brevity, conventional techniques for mechanical system construction, management, operation, measurement, optimization, and/or control, as well as conventional techniques for mechanical power transfer, modulation, control, and/or use, may not be described in detail herein. Furthermore, the connecting lines shown in various figures contained herein are intended to represent example functional relationships and/or physical couplings between various elements. It should be noted that many alternative or additional functional relationships or physical connections may be present in a modular structure.

A “battery array” as described herein refers to a plurality of batteries electrically coupled together. The term “array” is not meant to be limiting as to size, shape, configuration or the like. Any configuration of batteries coupled in series and/or parallel to form a battery system is within the scope of this disclosure.

Typically, battery systems are designed and configured for specific applications. In this regard, various applications have varying design considerations, such as capacity, discharge profiles, discharge frequency, structural capabilities, etc. Thus, various battery systems use various types of cells, configurations, or the like based on the specific design considerations for the battery system. In contrast, disclosed herein is a system with cross-compatible battery modules for two different and distinct systems. In this regard, in accordance with various embodiments, an aircraft battery system and a microgrid charging system may each be configured to utilize a plurality of battery modules, each battery module being cross-compatible with the other system.

Thus, disclosed herein are battery modules having common interfaces for a charging system (e.g., a mobile charging system) and an aircraft battery system. For example, the charging system may have a plumbing system, a communication system, a venting system, and/or electrical connections between adjacent battery modules. Similarly, the aircraft battery system may have a plumbing system, a communication system, a venting system, and/or electrical connections between adjacent battery modules. Locally, couplings between external components of the charging system to a respective battery module may be identical, or nearly identical to couplings between the aircraft battery system and the respective battery module.

Although described herein with respect to mobile charging systems, the present disclosure is not limited in this regard. For example, any charging system disclosed herein may comprise a stationary, fixed, and/or non-moveable charging system and be within the scope of this disclosure.

In various embodiments, by having cross-compatible battery modules, the microgrid charging system may be configured to act, at least partially, as inventory for battery modules of the aircraft battery system. In this regard, if it is determined a battery module of the aircraft battery system is no longer airworthy, a battery module of the microgrid charging system that is airworthy may replace the non-airworthy battery module with relative ease.

In various embodiments, by having cross-compatible battery modules, the microgrid charging system may further be configured to act, at least partially, as a secondary life for battery modules of the aircraft battery system. In this regard, a battery that is no longer airworthy may still be utilized in the microgrid charging system in this secondary life application due to less stringent structural and capacity related criteria for the microgrid charging system relative to the aircraft battery system, in accordance with various embodiments.

In various embodiments, the microgrid charging system is configured to charge the aircraft battery system. In various embodiments, the aircraft battery system is configured to power an electrically powered aircraft (e.g., a drone, an autonomous aircraft, an electrically powered manned aircraft, etc.).

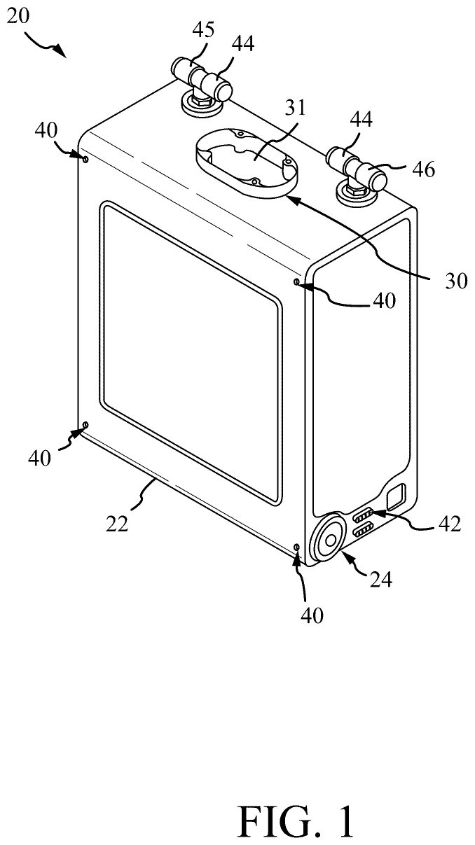

Referring now to FIG. 1, a perspective view of an interconnected battery module (“ICBM”) 20 is illustrated, in accordance with various embodiments. In various embodiments the ICBM 20 includes a housing 22 and a plurality of cells disposed within the housing 22. The plurality of cells are in electrical communication with power connections 24 disposed on opposite sides of the housing 22. The power connections 24 include a positive terminal and a negative terminal. In various embodiments, the plurality of cells are a plurality of pouch cells, a plurality of cylindrical cells, a plurality of prismatic cells, or the like. The present disclosure is not limited in this regard.

In various embodiments, the power connections 24 include a positive terminal on a first side and a negative terminal on a second side opposite the first side. The positive terminal is configured to electrically and physically couple to a negative terminal of an adjacent ICBM in an interconnected battery system described further herein. Similarly, the negative terminal is configured to electrically and physically couple to a positive terminal of an adjacent ICBM in an interconnected battery system. In this regard, the ICBMs of an interconnected battery system may be configured for electrical and physical coupling in series electrically and may be configured with an additional component to create a parallel electrical connection, in accordance with various embodiments. The present disclosure is not limited in this regard. For example, the interconnected battery system may be configured to couple adjacent ICBMs in parallel as a default configuration instead of in series as a default configuration and still be within the scope of this disclosure.

In various embodiments, the housing 22 includes a vent connection 30. In various embodiments, the vent connection 30 is configured to fluidly couple a vent port 31 to an exhaust system for a battery system as described further herein. In this regard, the vent connection 30 may comprise a common interface with an exhaust system for multiple battery systems, as described further herein, to facilitate swapping between battery systems for secondary life, or for primary life after being in inventory, in accordance with various embodiments. The vent port 31 comprises a fluid outlet in fluid communication with an internal cavity of the housing 22. The plurality of cells are also disposed in the internal cavity. In this regard, any ejecta, gases, or foreign object debris (“FOD”) from a thermal runaway event may be configured to be expelled out the vent port 31 and into an exhaust system of a respective battery system. In various embodiments, the vent connection 30 is disposed on a top surface of the housing.

In various embodiments, the housing 22 of the ICBM 20 comprises mounting connections 40 (e.g., physical mounting connections). The mounting connections 40 are configured to mount to a support structure in a respective battery system. In various embodiments, the mounting connections 40 may be disposed on opposite sides of the housing 22. However, the present disclosure is not limited in this regard. The mounting connections 40 may comprise a common interface with a support structure for multiple battery systems (e.g., a charging system and an electrically powered propulsion system), as described further herein.

In various embodiments, the ICBM 20 further comprises battery management connections 42. The battery management connections 42 may comprise daisy chain communication interfaces or the like. In this regard, the battery management connections 42 are configured to interface with adjacent ICBMs in accordance with ICBM 20 in a battery system and communicate data from the ICBM 20 down a line of adjacent ICBMs. In an example embodiment, the data from the various ICBMs is communicated to a master battery management system, in accordance with various embodiments. However, in other example embodiments, the battery management system is implemented in a distributed manner, or otherwise. This method of data communication may facilitate installing adjacent array of battery modules and maintaining data communication for a battery management system for various battery systems (e.g., a charging system and an electrically powered propulsion system), as described further herein.

In various embodiments, the ICBM 20 further comprises thermal management connections 44. The thermal management connections 44 are fluid connections, such as fittings, adapters, ferrules, or any type of fluid coupling known in the art. In various embodiments, the thermal management connections 44 comprise an inlet fitting 45 and an outlet fitting 46. In this regard, the ICBM 20 is configured to receive a fluid from the inlet fitting 45, which travels through the housing 22 and is configured to cool or heat a plurality of cells disposed within the housing 22, in accordance with various embodiments. In various embodiments, the thermal management connections 44 are adaptable to a battery system for an aircraft and adaptable for a charging system (e.g., a mobile charging system) as described further herein.

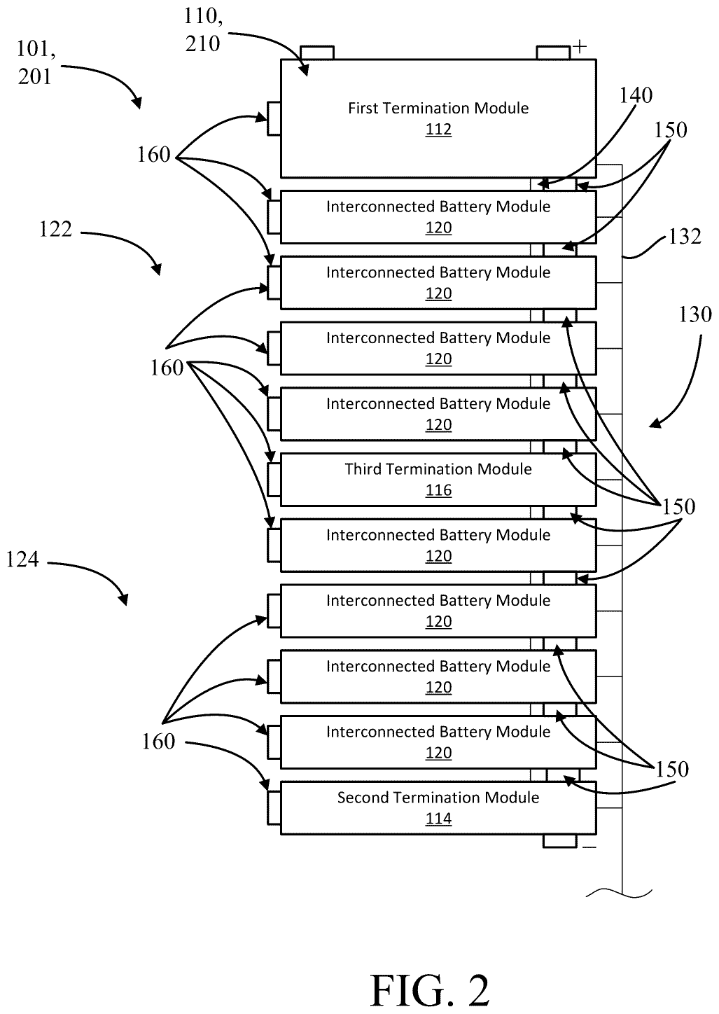

Referring now to FIG. 2, a schematic view of a portion of a battery system 101, 201 is illustrated, in accordance with various embodiments. In various embodiments, the portion of the battery system 101, 201 may be a portion of a battery system for an aircraft (e.g., to electrically power the aircraft) or a portion of a battery system for a charging system (e.g., a mobile charging system) for the aircraft.

The battery system 101, 201 comprises the battery management system 110, 210 and a plurality of ICBMs 120. In a configured state, the ICBMs 120 are disposed between a first termination module 112 (e.g., high side termination module) of the battery management system 110, 210 and a second termination module 114 (e.g., low side termination module) of the battery management system 110, 210. In various embodiments, “high side” as described herein may refer to an electrically positive end of a sequence of ICBMs 120 and a “low side” may refer to an electrically negative end of a sequence of ICBMs 120 in a battery system 101, 201.

In various embodiments, battery management system 110, 210 may further comprise a third termination module 116 disposed between the first termination module 112 and the second termination module 114. The third termination module 116 may further be disposed between a first set of ICBMs 122 of the ICBMs 120 and a second set of ICBMs 124 of the ICBMs 120. In various embodiments, the battery system 101, 201 may comprise at least one string of battery modules (e.g., the ICBMs 120 and the termination modules 112, 114, 116). A string of battery modules may be electrically coupled to an adjacent string of battery modules in a parallel configuration to increase a current provided by the battery system 101, 201, as described further herein

In an example embodiment, an ICBM (e.g., ICBM 20 from FIG. 1) in the plurality of ICBMS 120 as disclosed herein may comprise a nominal voltage of approximately 39 volts, a capacity of approximately 58 ampere-hours, an energy output of approximately 2.3 kWh, or the like. Although an example ICBM (e.g., ICBM 20 from FIG. 1) may have these specifications, an ICBM of any specification is within the scope of this disclosure. In an example embodiment, a 1,000 volt ICBM system may be created by interconnecting one-hundred and thirty-six ICBMs in series as disclosed herein. In various embodiments, by having each ICBM (e.g., ICBM 20 from FIG. 1) isolated and discrete from the remaining ICBMs 120, a thermal runaway event may be limited to a single ICBM where the thermal runaway event occurs. In this regard, in accordance with various embodiments, an ICBM (e.g., ICBM 20 from FIG. 1), as disclosed herein, may be configured to contain a thermal runaway event of a cell disposed in the ICBM without affecting any cell in any of the remaining ICBMs.

In various embodiments, the battery system 101, 201 may further comprise a thermal management system 130 and a communication system 140. In various embodiments, the thermal management system 130 is configured to cool (or heat) each module (e.g., ICBMs 120 and termination modules 112, 114, 116) in the battery system 101, 201. In various embodiments, the thermal management system 130 includes plumbing 132 external to the modules (e.g., ICBMs 120 and termination modules 112, 114, 116) and internal to each module. In various embodiments, the plumbing 132 for battery systems 101, 201 from FIG. 2 includes fluid conduits, such as pipes or the like routed between adjacent ICBMs in the plurality of ICBMs 120. The plumbing 132 interfaces with the thermal management connections (e.g., thermal management connections 44 from FIG. 1) of each ICBM in the plurality of ICBMs 120. In this regard, a common plumbing interface (e.g., thermal management connections 44 from FIG. 1) may exist for each ICBM in the plurality of ICBMs 120.

In various embodiments, the communication system 140 may include a daisy chain wiring scheme extending from the first termination module 112 and electrically coupling the termination modules 112, 114, 116 through the ICBMs 120. In this regard, the communication system 140 provides an electrical communication path throughout the battery management system 110, 210. For example, a controller disposed in the first termination module 112 may send a command signal to the second termination module 114 to perform various functions through the communication system 140. In various embodiments, the communication system 140 includes battery management connections 42 from the ICBM 20 of FIG. 1. In this regard, each ICBM in the plurality of ICBMs is configured to create a communication electrical coupling with an adjacent ICBM in the plurality of ICBMs 120 or an adjacent termination module (e.g., one of termination modules 112, 114, 116) to facilitate communication with the battery management system 110, 210, in accordance with various embodiments. In this regard, a common communications interface (e.g., battery management connections 42 from FIG. 1) may exist for each ICBM in the plurality of ICBMs 120. Thus, an ICBM 20 from FIG. 1 may be swapped from a first battery system (e.g., a battery system for an electrically powered aircraft) to a second battery system (e.g., a mobile charging system for the electrically powered aircraft) and communicate battery data to the battery management system of the second battery system in a manner similarly provided to a battery management system of the first battery system, in accordance with various embodiments.

In various embodiments, the battery system 101, 201 may further comprise a plurality of electrical interfaces 150 (e.g., power connections 24 from FIG. 1) between adjacent modules (e.g., between adjacent ICBMs 120, between a termination module and an ICBM 20, etc.). In various embodiments, the electrical interfaces 150 may be configured to electrically couple a positive terminal of a first module (e.g., termination modules 112, 114, 116 and ICBMs 120) to a negative terminal of a second module (e.g., termination modules 112, 114, 116 and ICBMs 120). Thus, a default electrical connection between adjacent modules (e.g., between adjacent ICBMs 120, between a termination module and an ICBM 20, etc.) may be an electrical series connection. Although described herein as having a series connection as a default electrical interface, the present disclosure is not limited in this regard. For example, the electrical interface 150 may be configured for parallel connections (i.e., negative terminal interfacing with an adjacent negative terminal), in accordance with various embodiments. A common electrical interface (e.g., power connections 24 from FIG. 1) may exist for each ICBM in the plurality of ICBMs 120. Thus, the common electrical interfaces of an ICBM 20 from FIG. 1 may facilitate swapping from a first battery system (e.g., a battery system for an electrically powered aircraft) to a second battery system (e.g., a mobile charging system for the electrically powered aircraft) as described further herein.

In various embodiments, the battery system 101, 201 further comprises a plurality of mechanical interfaces 160 (e.g., mounting connections 40 of ICBM 20 from FIG. 1). Although illustrated as only being on a single side of each ICBM in the plurality of ICBMs, the present disclosure is not limited in this regard. For example, mounting connections 40 of ICBM 20 from FIG. 1 may be on any number of sides and include any number of physical interfaces and be within the scope of this disclosure. A common mounting interface (e.g., mounting connections 40 from FIG. 1) may exist for each ICBM in the plurality of ICBMs 120. Thus, the common physical interfaces of an ICBM 20 from FIG. 1 may facilitate swapping from a first battery system (e.g., a battery system for an electrically powered aircraft) to a second battery system (e.g., a mobile charging system for the electrically powered aircraft) where a support structure of each battery system includes complimentary interfaces to mate with the mounting connections 40 of ICBM 20 from FIG. 1 as described further herein. In various embodiments, the mounting connections 40 of ICBM 20 from FIG. 1 may comprise bolt holes, threaded holes, studs configured to interface with bolt holes/threaded holes, etc. The present disclosure is not limited in this regard.

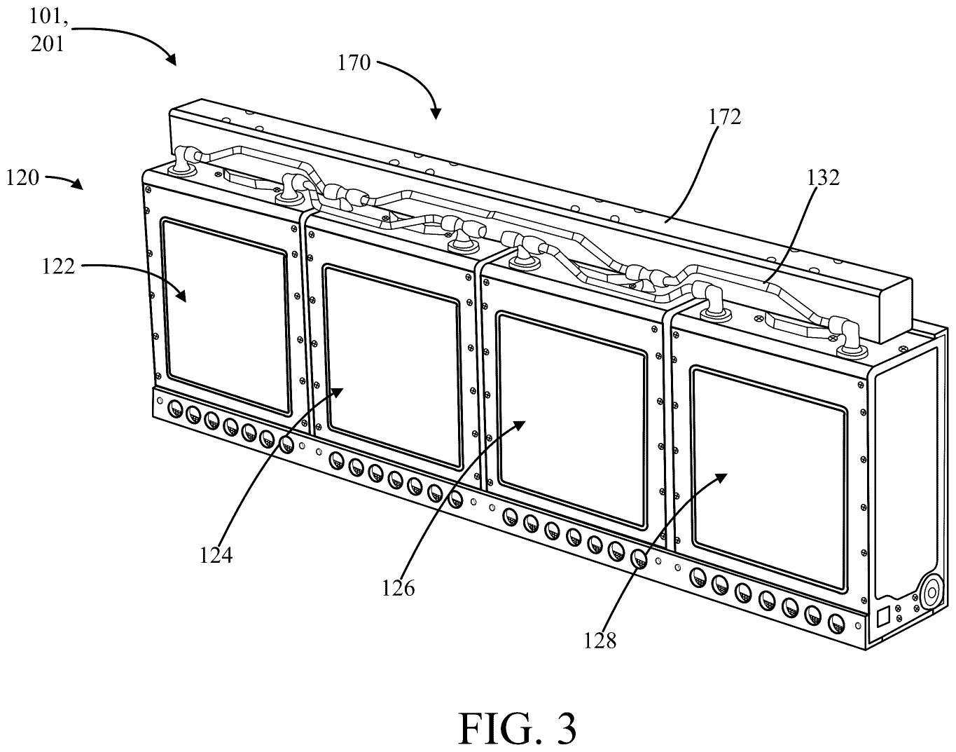

Referring now to FIG. 3, a perspective view of a portion the battery system 101, 201 from FIG. 2 is illustrated, in accordance with various embodiments. The battery system 101, 201 includes the plurality of ICBMs 120 (e.g., ICBM 122, 124, 126, 128). Each ICBM is electrically coupled to an adjacent ICBM (e.g., ICBM 122 is electrically coupled to ICBM 124, ICBM 124 is electrically coupled to ICBM 126, and ICBM 126 is electrically coupled to ICBM 128) via common electrical interfaces (e.g., power connections 24 from FIG. 1).

Each ICBM is also fluidly coupled to an adjacent ICBM (e.g., ICBM 122 is fluidly coupled to ICBM 124, ICBM 124 is fluidly coupled to ICBM 126, ICBM 126 is fluidly coupled to ICBM 128) via common fluid connections and the plumbing 132. In this regard, a portion of plumbing for a first battery system (e.g., a battery system for an electrically powered aircraft) and a second battery system (e.g., a mobile charging system for the electrically powered aircraft) may be the same. For example, plumbing 132 between adjacent battery modules (e.g., ICBM 122 and ICBM 124) may be maintained between the first battery system and the second battery system as described further herein.

Each ICBM may also be fluidly coupled to an adjacent ICBM (e.g., ICBM 122 is fluidly coupled to ICBM 124, ICBM 124 is fluidly coupled to ICBM 126, ICBM 126 is fluidly coupled to ICBM 128) via a common vent 172 and a vent connection for each ICBM (e.g., vent port 31 from FIG. 1). In this regard, each vent connection (e.g., vent connection 30 from FIG. 1) may be physically coupled to the common vent 172 of a vent system 170 for the battery system 101, 201.

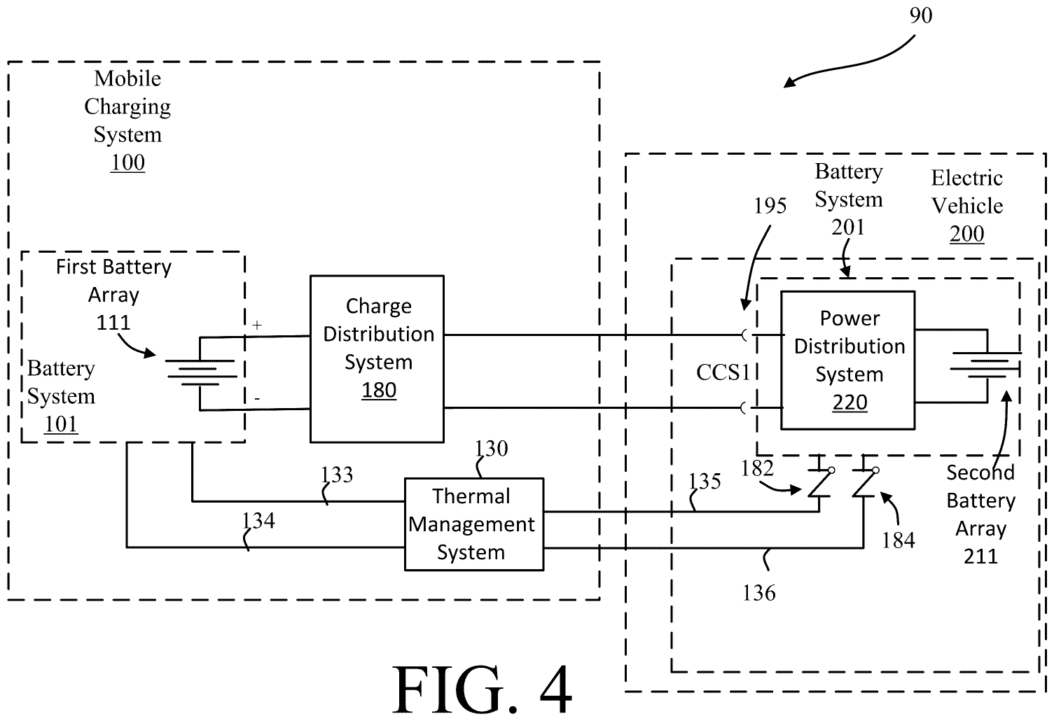

Referring now to FIG. 4, a schematic view of an electric vehicle charging ecosystem 90 is illustrated, in accordance with various embodiments. The electric vehicle charging ecosystem 90 may be configured for charging an electrically powered aircraft (e.g., a battery powered aircraft or the like) in accordance with various embodiments. The electric vehicle charging ecosystem 90 comprises a charging system 100 (e.g., a mobile charging system) and an electric vehicle 200 (e.g., an electric aircraft) with the battery system 201. The charging system 100 comprises the battery system 101 from FIGS. 2 and 3 having a first battery array 111 (e.g., a plurality of ICBMS such as ICBMs 122, 124, 126, 128 from FIG. 3). Similarly, the electric vehicle 200 comprises the battery system 201 from FIGS. 2 and 3 having a second battery array 211 (e.g., a plurality of ICBMS such as ICBMs 122, 124, 126, 128 from FIG. 3). The second battery array 211 is configured to power the electric vehicle (e.g., an electric powered aircraft or the like), in accordance with various embodiments. The first battery array 111 is configured to charge the second battery array 211.

In various embodiments, the charging system 100 is a mobile charging system. A “mobile charging system” as referred to herein refers to a battery system fixedly coupled to a wheeled vehicle (e.g., a truck, a lift, a van, a bus, a specialty vehicle or the like), a non-wheeled vehicle (e.g., vehicle with continuous track system, train system, etc.). In this regard, the charging system 100 may be configured to be transported from a fixed charging station (e.g., configured to charge the charging system 100) to an electric vehicle 200 (e.g., an electric aircraft) being charged via the charging system 100. Although described herein as a mobile charging system, the present disclosure is not limited in this regard. For example, a stationary, fixed, and/or non/moveable charging system is within the scope of this disclosure, in accordance with various embodiments.

As described previously herein, each ICBM in the battery systems 101, 201 may comprise a nominal voltage of approximately 39 volts, a capacity of approximately 58 ampere-hours, an energy output of approximately 2.3 kWh, or the like. Thus, a number of ICBMs in the battery system 101 and the battery system 201 may be different to achieve a different total voltage and/or a different energy output relative to each other. Additionally, the battery management system 110 from FIG. 2 for battery system 101 may be configured to provide different inputs into battery system 101 relative to the battery management system 210 for battery system 201. In this regard, battery management system 210 may command a different discharge profile for battery system 201 relative to battery management system 110 for battery system 101, in accordance with various embodiments. Thus, by maintaining a modular and common ICBM between both battery system 101, 201, customizing various inputs from a battery management system and varying a number of ICBMs in each battery system 101, 201 may facilitate differing discharge profiles, charging profiles, power output, etc. Thus, both the charging system 100 and the electric vehicle 200 may include a battery system (e.g., battery system 101 and battery system 201 respectively) customized and configured for the specific application, but utilizing the same modular ICBMs, in accordance with various embodiments.

In various embodiments, the charging system 100 further comprises a charge distribution system 180 in electrical communication with the battery system 101 and the thermal management system 130. The charge distribution system is configured to be electrically coupled to a power distribution system 220 of the electric vehicle 200, in accordance with various embodiments. In various embodiments, the electric vehicle charging ecosystem 90 comprises a combined charging system (CCS) 195 configured for high-power DC fast charging. Although illustrated as comprising a United States style combined charging system (“CCS1”), the charging system is not limited in this regard. For example, the combined charging system 195 may comprise a European style combined charging system (“CCS2”), Chademo, GBT, or any other emerging aerospace standard charging system, in accordance with various embodiments.

The thermal management system 130 is in fluid communication with the battery system 101 via a supply fluid conduit 133 and a return fluid conduit 134. In various embodiments, the thermal management system 130 is configured to supply fluid through the battery system 101 via the fluid conduits 133, 134 and plumbing 132 of battery system 101 from FIG. 2. In this regard, a first fluid conduit in the plumbing 132 of battery system 101 from FIG. 2 may be coupled to the supply fluid conduit 133, and the return fluid conduit 134 may be coupled to a second fluid conduit in the plumbing 132 of battery system 101 from FIG. 2, in accordance with various embodiments. In various embodiments, each ICBM in the battery system 101 may maintain a same fluid conduit interface with all other ICBMs in the battery system 101. In various embodiments, ends of a string of ICBMs in a battery system 101 may have different fluid interfaces relative to ICBMs disposed between adjacent ICBMs in the battery system 101. The present disclosure is not limited in this regard.

The thermal management system 130 is configured to be in fluid communication with the battery system 201 via a supply fluid conduit 135 and a return fluid conduit 136. In this regard, the fluid conduits 135, 136 may each comprise quick disconnect fittings 182, 184 configured to fluidly couple the thermal management system 130 to the battery system 201. In this regard, during charging of the second battery array 211 via the first battery array 111, the thermal management system may supply fluid to heat or cool the second battery array 211, in accordance with various embodiments.

In various embodiments, the thermal management system 130 is configured to supply fluid through the battery system 201 via the fluid conduits 136, 136 and plumbing 132 of battery system 201 from FIG. 2. In this regard, a first fluid conduit in the plumbing 132 may be coupled to the supply fluid conduit 135 and the return fluid conduit 136 of battery system 201 from FIG. 2 may be coupled to a second fluid conduit in the plumbing 132 of battery system 201 from FIG. 2, in accordance with various embodiments. In various embodiments, each ICBM in the battery system 201 may maintain a same fluid conduit interface with all other ICBMs in the battery system 201. In various embodiments, ends of a string of ICBMs in a battery system 201 may have different fluid interfaces relative to ICBMs disposed between adjacent ICBMs in the battery system 101. The present disclosure is not limited in this regard.

In various embodiments, by having common plumbing (e.g., plumbing 132 of battery system 201 from FIG. 2) between adjacent ICBMs in both battery systems 101, 201, the ICBMs may be swappable between battery systems and maintain fluid interfaces regardless of which system (e.g., battery system 101 or battery system 201) the ICBM is installed in.

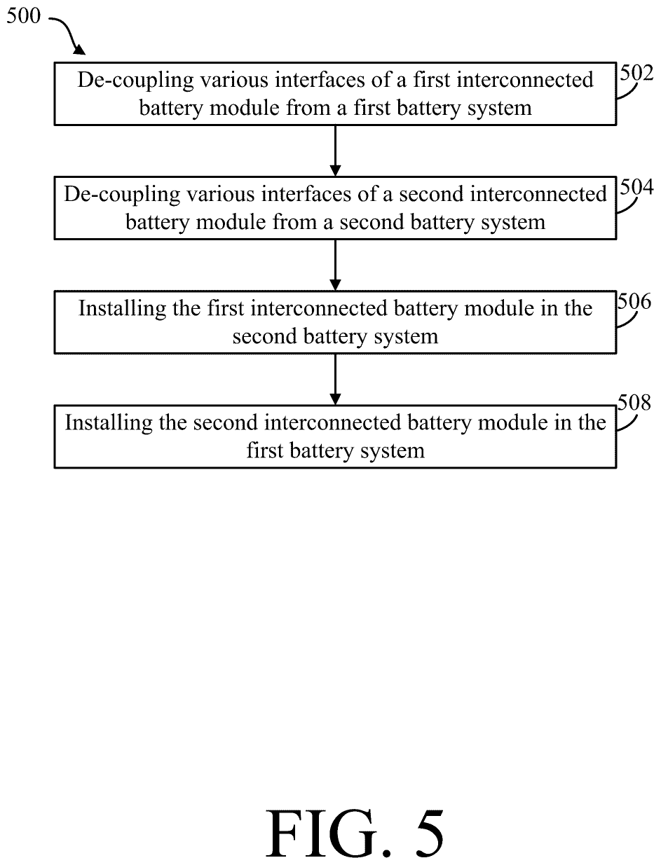

Referring now to FIG. 5, a method 500 for swapping an ICBM from a first battery system with a second ICBM from second battery system is illustrated, in accordance with various embodiments. The method 500 comprises de-coupling various physical interfaces of a first ICBM from a first battery system (step 502). The first battery system may be a battery system 201 for an electric vehicle 200 as shown in FIG. 4, in accordance with various embodiments. For example, in response to an ICBM no longer meeting an airworthiness standard for an electrically powered aircraft, a battery module may have to be replaced with a battery module that does meet the airworthiness standard. As an airworthiness standard may be a heightened standard relative to other battery systems, such as charging battery systems, the ICBM being replaced may still have value in the charging system (e.g., charging system 100 from FIG. 4). Thus, the ICBM being replaced in the electric vehicle 200 from FIG. 4 may be re-purposed for a secondary life within charging system 100 from FIG. 4 as described further herein.

In various embodiments, de-coupling various physical interfaces may include de-coupling the ICBM (1) from various systems of the first battery system (e.g., vent connection 30 of FIG. 1 from an exhaust system and/or thermal management connections 44 of FIG. 1 from a thermal management system), (2) from adjacent ICBMs in the first battery system (e.g., power connections 24 and battery management connections 42), and/or (3) from a support structure for the first battery system (e.g., mounting connections 40 from FIG. 1). De-coupling from the support structure may include de-coupling the first ICBM from the support structure that supports the first battery system during operation. In various embodiments, the support structure for the first battery system may be in an electrically powered aircraft.

In this regard, de-coupling from the systems of the first battery system may include de-coupling a first thermal management connection from a first fluid conduit and de-coupling a second thermal management connection from a second fluid conduit. Thus, the ICBM of the first battery system may be de-coupled from plumbing associated with a thermal management system of the first battery system. Similarly, the vent connections may be de-coupled from a vent system (e.g., including a common vent 172 as shown in FIG. 3).

De-coupling from adjacent ICBMs may include de-coupling the power connections and the battery management communications connections. In this regard, the ICBM may be de-coupled electrically from the first battery system.

The method 500 further comprises de-coupling various interfaces of a second ICBM from a second battery system (step 504). The second battery system may be the battery system 101 for the charging system 100 from FIG. 1. In this regard, a set of ICBMs in the first battery array 111 may be installed in the battery system 101 as inventory. In this regard, the set of ICBMs installed in the battery system 101 as inventory may be designated as such and monitored to ensure an airworthiness standard is continuously met. Thus, in response to the battery system 201 of the electric vehicle 200 having an ICBM that no longer meets the airworthiness standard, an ICBM from the set of ICBMs designated as inventory may be de-coupled from the second battery system in accordance with step 504 and installed in the battery system 201 of the electric vehicle 200 as described further herein.

In various embodiments, de-coupling various physical interfaces of the second ICBM from the second battery system may include de-coupling the ICBM (1) from various systems of the second battery system (e.g., vent connection 30 of FIG. 1 from an exhaust system and/or thermal management connections 44 of FIG. 1 from a thermal management system), (2) from adjacent ICBMs in the first battery system (e.g., power connections 24 and battery management connections 42), and/or (3) from a support structure for the second battery system (e.g., mounting connections 40 from FIG. 1). Thus, the second ICBM may be de-coupled from all mating interfaces from the second battery system in a manner similar to the de-coupling of the first ICBM from the first battery system.

The method 500 further comprises installing the first ICBM in the second battery system (step 506). In this regard, installing the first ICBM in the second battery system may include coupling various physical interfaces of the first ICBM to the second battery system. For example, coupling various physical interfaces of the first ICBM to the second battery system may include coupling the ICBM (1) to various systems of the second battery system (e.g., vent connection 30 of FIG. 1 to an exhaust system and/or thermal management connections 44 of FIG. 1 to a thermal management system), (2) to adjacent ICBMs in the second battery system (e.g., power connections 24 and battery management connections 42), and/or (3) to the support structure for the second battery system (e.g., mounting connections 40 from FIG. 1). Thus, the first ICBM may essentially be swapped into the second ICBM's prior location, physically coupled to the thermal management system and exhaust system, electrically coupled to the power distribution and power communications systems, and physically coupled to the support structure in an efficient manner, in accordance with various embodiments.

The method 500 further comprises installing the second ICBM in the first battery system (step 508). In this regard, installing the second ICBM in the first battery system may include coupling various physical interfaces of the second ICBM to the first battery system. For example, coupling various physical interfaces of the second ICBM to the first battery system may include coupling the ICBM (1) to various systems of the first battery system (e.g., vent connection 30 of FIG. 1 to an exhaust system and/or thermal management connections 44 of FIG. 1 to a thermal management system), (2) to adjacent ICBMs in the first battery system (e.g., power connections 24 and battery management connections 42), and/or (3) to the support structure for the first battery system (e.g., mounting connections 40 from FIG. 1). Thus, the second ICBM may essentially be swapped into the first ICBM's prior location, physically coupled to the thermal management system and exhaust system, electrically coupled to the power distribution and power communications systems, and physically coupled to the support structure in an efficient manner, in accordance with various embodiments.

Although described herein as swapping the ICBMs, the present disclosure is not limited in this regard. For example, the first ICBM may replace the second ICBM as described herein and a third ICBM may replace the first ICBM, in accordance with various embodiments. For example, the third ICBM could be a brand new ICBM entering the system

While the principles of this disclosure have been shown in various embodiments, many modifications of structure, arrangements, proportions, elements, materials and components (which are particularly adapted for a specific environment and operating requirements) may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above regarding various embodiments.

However, benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

We claim:

1. A charging ecosystem, comprising:
an interconnected battery module comprising a housing, thermal management connections configured to interface with plumbing, power connections, and communications connections;
a charging system comprising a first plurality of the interconnected battery module, each of the first plurality of the interconnected battery module electrically coupled to a first positive terminal or a first negative terminal in the power connections of a first adjacent interconnected battery module in the first plurality of the interconnected battery module; and
an aircraft battery system comprising a second plurality of the interconnected battery module, each of the second plurality of the interconnected battery module electrically coupled to a second positive terminal or a second negative terminal in the power connections of a second adjacent interconnected battery module in the second plurality of the interconnected battery module.

2. The charging ecosystem of claim 1, wherein the interconnected battery module further comprises vent connections and a vent port, the vent connections configured to be coupled to a vent system.

3. The charging ecosystem of claim 2, wherein the vent port is in fluid communication with a cavity disposed within the housing.

4. The charging ecosystem of claim 1, wherein the interconnected battery module further comprises mounting connections.

5. The charging ecosystem of claim 4, wherein a support structure of the charging system is coupled to the mounting connections for the first plurality of the interconnected battery module, and wherein a second support structure of the aircraft battery system is coupled to the mounting connections for the second plurality of the interconnected battery module.

6. The charging ecosystem of claim 5, wherein the support structure is disposed in a vehicle configured to transport the charging system, and wherein the second support structure is disposed in an electrically powered aircraft.

7. The charging ecosystem of claim 1, further comprising a thermal management system in fluid communication with the first plurality of the interconnected battery module via the thermal management connections.

8. The charging ecosystem of claim 7, wherein the thermal management system is configured to be fluidly coupled to the second plurality of the interconnected battery module via the thermal management connections in response to the thermal management system being fluidly coupled to the aircraft battery system during charging of the aircraft battery system.

9. A method of swapping battery modules, the method comprising:
de-coupling a first interconnected battery module from a first battery system;
de-coupling a second interconnected battery module from a second battery system; and
coupling the first interconnected battery module to the second battery system, the second battery system including plumbing for fluid communication with a thermal management system, a vent for an exhaust system, and a plurality of interconnected battery modules in electrical communication with each other and physically coupled to each other.

10. The method of claim 9, wherein the first interconnected battery module and the second interconnected battery module each comprise a vent connection and thermal management connections.

11. The method of claim 10, wherein the vent connection of the first interconnected battery module is configured to fluidly couple a first internal cavity of the first interconnected battery module to the vent for the exhaust system in response to coupling the first interconnected battery module to the second battery system.

12. The method of claim 11, wherein the vent connection of the second interconnected battery module removes a coupling between a second internal cavity of the second interconnected battery module from the vent for the exhaust system in response to de-coupling the second interconnected battery module from the second battery system.

13. The method of claim 9, further comprising coupling the second interconnected battery module to the first battery system.

14. The method of claim 9, wherein the first battery system is a charging system for the second battery system, wherein the second battery system is configured to power an electric vehicle.

15. A method, comprising:
de-coupling a first interconnected battery module physically from a first thermal management system of a first battery system and electrically from a first set of adjacent interconnected battery modules in the first battery system; and
installing the first interconnected battery module in a second battery system by coupling the first interconnected battery module physically to a second thermal management system of the second battery system and electrically to a second set of adjacent interconnected battery modules in the second battery system.

16. The method of claim 15, wherein de-coupling the first interconnected battery module further comprises de-coupling a mounting interface from a first support structure of the first battery system, and wherein installing the first interconnected battery module in the second battery system further comprises coupling the mounting interface to a second support structure of the second battery system.

17. The method of claim 15, wherein installing the first interconnected battery module in the second battery system further comprises coupling a vent connection to a common vent of an exhaust system, coupling thermal connections to a thermal management system, coupling power connections to the second set of adjacent interconnected battery modules, and coupling communications connections to the second set of adjacent interconnected battery modules.

18. The method of claim 15, wherein the first battery system is a charging system for an electric vehicle, and wherein the second battery system is an electric vehicle battery system for the electric vehicle.

19. The method of claim 15, wherein the first battery system is an electric vehicle battery system for an electric vehicle, and wherein the second battery system is a charging system for the electric vehicle.

20. The method of claim 15, wherein the first thermal management system is the second thermal management system in response to the first battery system being configured to charge the second battery system.
